(19) United States
(12) Patent Application Publication
(10) Pub. No.: US 2026/0113839 A1
(43) Pub. Date: Apr. 23, 2026

(54) Integrated Printed Wiring Board Coin with Horizontal Heat Channel and Edge Exposure

(71) Applicant: Rockwell Collins, Inc., Cedar Rapids, IA (US)

(72) Inventors: Jeffrey D. SCHMIDT, Marion, IA (US); Mark B. FREDIN, Marion, IA (US); Kyle D. ANDREWS, Cedar Rapids, IA (US)

(73) Assignee: Rockwell Collins, Inc., Cedar Rapids, IA (US)

(21) Appl. No.: 18/924,191

(22) Filed: Oct. 23, 2024

(51) Int. Cl. H05K 1/11; H05K 1/02; H05K 1/18; H05K 3/46; H05K 7/20

(52) U.S. Cl. CPC H05K 1/111; H05K 1/0203; H05K 1/181; H05K 3/46; H05K 7/20336

(57) ABSTRACT

A printed circuit board or wiring board, containing a multilayer structure forming the PCB/PWB, which has a top surface, a bottom surface and several sides, embedded within the PCB/PWB a coin made of a material having improved heat conducting properties compared to the material of the PCB/PWB, wherein the coin has at least one exposed area at the top and/or bottom surface of the PCB/PWB onto which exposed area an electronic component can be attached, wherein the coin has an exposed area at the opposite surface of the PCB/PWB, and wherein at least one part of the coin extends to at least one side of the PCB/PWB where the at least one part is exposed on a side of the PCB/PWB, or where at least one part of the coin extends past at least one side of the PCB/PWB where at least one part extending is exposed.

### FIELD OF THE INVENTION

The subject matter disclosed herein relates to the cooling of electronic components installed on printed circuit boards (PCBs) or printed wiring boards (PWBs), i.e., PCB/PWB, which may be used interchangeably herein, and, in particular, to the use of press-fit coins, embedded coins, filled thermal features, e.g., engineered thermal paste, or advanced exotic thermal design technique, such as, e.g., heat pipes, including oscillating or pulsating heat pipes, to create both vertical and horizontal heat paths to remove heat from electronic components.

Noted up front is that a coin, unless specified to be made of a certain material, such as metal (which is the common understanding in this art, i.e., that a coin is metal, typically copper), for the purposes of this application is understood to be inclusive of all materials that have a higher thermal conductivity than the surrounding material forming the PCB/PWB, and is inclusive of non-electrically conductive materials also that are thermally conductive, and is also inclusive of filled thermal features or sintered features, and likewise inclusive of non-metal materials.

### BACKGROUND OF THE INVENTION

As circuit boards have become more and more sophisticated with higher and faster capacities to accomplish tasks, while at the same time there is a demand for delivering such circuit boards in smaller packages, a limiting and challenging aspect has become the removal of heat generated by densely integrated powerful electronic components, such as, for example, chips. In other words, the increased power densities and higher transistor densities for increased processing, higher clock speeds for increased processing, higher performance analog-to-digital converters for improved SWAP (Size, Weight, and Power), higher performance analog-to-digital converters for improved SWAP, higher dissipation RF amplifiers for increased RF output power, and many others, all in reduced size circuit boards leads to increased heat being generated, which needs to be efficiently removed for the proper and consistent operation of circuit boards and chips thereon, while maintaining small package configurations. Small and lightweight electronics packages, e.g., with smaller chassis, while having good heat management, are highly desired and beneficial, especially in certain industries, like aviation, aerospace, military and in many others. Moreover, with reduced sized electronics packages certain costs are also reduced, for example, costs for materials, costs associated with elaborate chassis design and fabrication, thermal solution costs, etc.

To remove heat from a circuit board, various thermal paths may be provided to move heat away from the electronic components, e.g., chips, and toward the exterior of circuit boards, e.g., the surrounding environment or other heat sinks. Portions of these thermal paths may be provided in the circuit board itself, including all portions thereof.

One approach to removing heat from circuit boards is by providing copper or other metal structures within the board that have lower resistance to the flow of heat. The metal structures may be in various form, for example, a metal coin being embedded within a circuit board's substrate. In the most common form, a coin may be embedded in a multilayer printed circuit board (PCB) or printed wiring board (PWB) by providing laminates above, below and/or around the coin, by a plating process, by installed post PCB/PWB fabrication by press fitting the coin into a cavity formed in the substrate by mechanical force. Installation and/or embedment of the coin may be aided by mechanical drilling, laser drilling, and/or by sintering techniques.

### SUMMARY OF THE INVENTION

The present disclosure is directed, in a first aspect, to a printed circuit board or printed wiring board (PCB/PWB), containing a multilayer structure forming the PCB/PWB, which has a top surface, a bottom surface and several sides, embedded within the PCB/PWB a coin made of a material having higher heat conducting properties compared to the material of the PCB/PWB, wherein the coin has at least one exposed area at the top surface of the PCB/PWB onto which exposed area an electronic component can be attached, wherein the coin has at least one exposed area at the bottom surface of the PCB/PWB, and wherein at least one part of the coin extends to a side of the PCB/PWB where said at least one part is exposed on a side of the PCB/PWB, or where at least one part of the coin extends past a side of the PCB/PWB where said at least one part extending is exposed.

In yet another embodiment further to the first aspect, the present disclosure is directed to a printed circuit board or printed wiring board that further contains an electronic component that is attached to the coin at the at least one exposed area at the top surface of the PCB/PWB.

In yet another embodiment further to the first aspect, the present disclosure is directed to a printed circuit board or printed wiring board that further contains a system heat sink that is connected to the coin extending to the side of the PCB/PWB or extending past the side of the PCB/PWB.

In yet another embodiment further to the first aspect, the present disclosure is directed to a printed circuit board or printed wiring board that further contains a system radiating or conducting surface that is connected to the coin extending to the side of the PCB/PWB or extending past the side of the PCB/PWB, wherein a thermal interface material is present between the coin and the system radiating or conducting surface or a system heat sink.

In yet another embodiment further to the first aspect, the present disclosure is directed to a printed circuit board or printed wiring board, wherein a part of the coin extends past a side of the PCB/PWB.

In yet another embodiment further to the first aspect, the present disclosure is directed to a printed circuit board or printed wiring board, wherein the at least one exposed area at the bottom surface of the PCB/PWB contains ridges or has a roughening to provide a higher surface area compared to an otherwise identical coin that has a smooth surface.

In yet another embodiment further to the first aspect, the present disclosure is directed to a printed circuit board or printed wiring board that further contains an electronic component that is attached to the coin at the at least one exposed area at the top surface of the PCB/PWB to which electronic component a chassis is connected through a thermal interface material, which chassis is connected to a system radiating or conducting surface through an optional thermal interface material.

In yet another embodiment further to the first aspect, the present disclosure is directed to a printed circuit board or printed wiring board that further contains an electronic component that is attached to the coin at the at least one exposed area at the top surface of the PCB/PWB, wherein the surface of the area of the exposed part of the coin at the bottom surface of the PCB/PWB is connected through a thermal interface material to a chassis, which chassis is connected to a system radiating or conducting surface through an optional thermal interface material.

In yet another embodiment further to the first aspect, the present disclosure is directed to a printed circuit board or printed wiring board, wherein two, three or four parts of the coin extend to two, three or four sides of the PCB/PWB where each are independently either exposed on a side of the PCB/PWB or extend past a side of the PCB/PWB.

In yet another embodiment further to the first aspect, the present disclosure is directed to a printed circuit board or printed wiring board, wherein two or more exposed areas of the coin are present at the top surface of the PCB/PWB onto each of which exposed areas an electronic component can be attached.

In yet another embodiment further to the first aspect, the present disclosure is directed to a printed circuit board or printed wiring board, wherein two or more exposed areas of the coin are present at the top surface of the PCB/PWB onto each of which exposed areas an electronic component has been attached directly by a solder material.

In yet another embodiment further to the first aspect, the present disclosure is directed to a printed circuit board or printed wiring board that further contains wiring traces in the PCB/PWB below and/or above and/or around parts of the coin.

In yet another embodiment further to the first aspect, the present disclosure is directed to a printed circuit board or printed wiring board, wherein the area of the exposed part of the coin at the bottom surface of the PCB/PWB represent at least 20% of the area of the bottom surface of the PCB/PWB.

In yet another embodiment further to the first aspect, the present disclosure is directed to a printed circuit board or printed wiring board that further contains an electronic component that is attached to the coin at the at least one exposed area at the top surface of the PCB/PWB and a system radiating or conducting surface that is connected to the coin extending to the side of the PCB/PWB or extending past the side of the PCB/PWB, wherein the electronic component and the system radiating or conducting surface are soldered to the coin.

An electronic package containing a printed circuit board or printed wiring board according to the first aspect inside a chassis or housing.

In yet another embodiment further to the first aspect, the present disclosure is directed to a printed circuit board or printed wiring board wherein different sections of the coin are each made of different homogeneous materials.

The present disclosure is directed, in a second aspect, to a printed circuit board or printed wiring board (PCB/PWB), containing a multilayer structure forming the PCB/PWB, which has a top surface, a bottom surface and several sides, embedded within the PCB/PWB a coin made of a material having higher heat conducting properties compared to the material of the PCB/PWB, wherein the coin has at least one exposed area at the top surface of the PCB/PWB onto which exposed area an electronic component can be attached, wherein the coin has at least one exposed area at the bottom surface of the PCB/PWB, wherein at least one part of the coin extends to a side of the PCB/PWB where said at least one part is exposed on a side of the PCB/PWB, or where at least one part of the coin extends past a side of the PCB/PWB where said at least one part extending is exposed; and comprising a heat pipe in at least one part of the coin extending to a side of the PCB/PWB or past a side of the PCB/PWB, or comprising a heat pipe in at least one part of the coin that can be in fluid communication with a heat sink.

In yet another embodiment further to the second aspect, the present disclosure is directed to a printed circuit board or printed wiring board, wherein the heat pipe is an oscillating or pulsating heat pipe that is a closed loop heat pipe.

In yet another embodiment further to the second aspect, the present disclosure is directed to a printed circuit board or printed wiring board, wherein the coin containing a heat pipe has been manufactured by an additive manufacturing technique.

In yet another embodiment further to the second aspect, the present disclosure is directed to a printed circuit board or printed wiring board, which contains a heat pipe in at least one part of the coin and extends past a side of the PCB/PWB such that part of the heat pipe is embedded in the coin and part of the heat pipe is external to the coin and also external to the PCB/PWB, and wherein a working fluid is present in the heat pipe and forms a working fluid loop that is partially inside the coin and partially exterior to the coin and PCB/PWB.

The present disclosure is directed, in a third aspect, to a process for preparing a printed circuit board or printed wiring board (PCB/PWB), said PCB/PWB containing a multilayer structure forming the PCB/PWB, which has a top surface, a bottom surface and several sides, embedded within the PCB/PWB a coin made up of a material having higher heat conducting properties compared to the material of the PCB or PWB, wherein the coin has at least one exposed area at the top surface of the PCB/PWB onto which exposed area an electronic component can be attached, wherein the coin has at least one exposed area at the bottom surface of the PCB/PWB, and wherein at least one part of the coin extends to a side of the PCB/PWB where said at least one part is exposed on a side of the PCB/PWB, or where at least one part of the coin extends past a side of the PCB/PWB where said at least one part extending is exposed; and said process including embedding the coin in the PCB/PWB by providing laminates above, below and/or around the coin, by a plating process, by installed post PCB/PWB fabrication by press fitting the coin into a cavity formed in the PCB/PWB by mechanical force or by the aid of laser drilling, or a sintering technique to form the coin in place.

A method of providing an electronics package that has enhanced heat removal properties, comprising providing in said electronics package a printed circuit board or printed wiring board according to the first aspect.

### BRIEF DESCRIPTION OF FIGURES

The features of the disclosure believed to be novel and the elements characteristic of the invention are set forth with particularity in the appended claims. The figures are for illustration purposes only and are not drawn to scale. The disclosure itself, however, both as to organization and method of operation, can best be understood by reference to the description of the preferred embodiment(s) which follows, taken in conjunction with the accompanying drawings in which:

FIG. 1 illustrates a top view of a PCB/PWB containing an embedded structure/coin. (Noted is that a top and bottom designations are used as reference designations of surfaces of PCBs/PWBs, but that the top and bottom designations may be interchangeable depending on perspective. In other words, while PCB/PWB drawings may label what one may call, e.g., a top, such may be vice versa understood by others to be a bottom depending on perspective.)

FIG. 2 illustrates a cross-sectional view of a PCB/PWB containing an embedded structure/coin.

FIG. 3 illustrates a top view of a PCB/PWB containing an embedded structure/coin and containing a heat pipe that removes heat, e.g., an oscillating or pulsating heat pipe.

FIG. 4 illustrates a cross-sectional view of a PCB/PWB containing an embedded structure/coin and containing a heat pipe, which can be an oscillating or pulsating heat pipe.

FIG. 5A illustrates a traditional vertical only bottom-side heat path design.

FIG. 5B illustrates a traditional vertical only top-side heat path design.

FIG. 6 illustrates an embodiment where multiple electronic components share the same coin as a heat path.

FIG. 7A illustrates an embodiment where an additional or secondary heat path is provided in addition to the heat path formed by the coin in the PCB/PWB.

FIG. 7B illustrates another embodiment where an additional or secondary heat path is provided in addition to the heat path formed by the coin in the PCB/PWB.

FIG. 7C illustrates an embodiment where two additional or secondary heat paths are provided in addition to the heat path formed by the coin in the PCB/PWB.

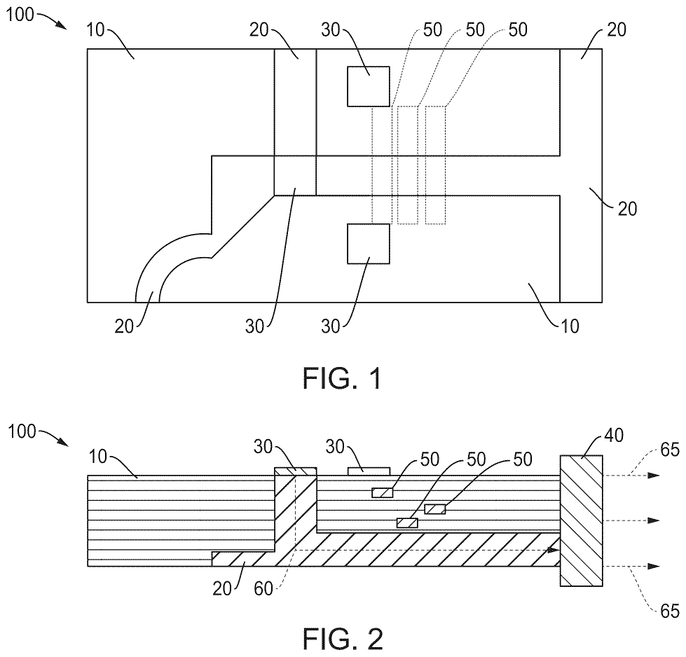

FIG. 1 illustrates an exemplary embodiment of a PCB/PWB (100). (While most discussion herein will refer to PCBs, it is to be understood that such discussion is equally applicable to PWBs as well and other electronic boards.) In the top view illustration provided by FIG. 1, a PCB's body (10) is shown that contains several electronic components (30), such as microchips, but not limited to, but rather inclusive of other components that may provide other functionality, which may be connected by various printed wiring board traces (50) that provide communication among the components, e.g., by the flow of electrical energy and/or data from one component to another. Examples of electronic components include, e.g., general processors, field programable gate arrays, graphics devices, radio frequency amplifiers, resistors, analog-to-digital converters, digital to analog converters, and many others.

An embedded structure (20), which may be called a coin, which may have various shapes other than a circular coin, is provided in the PCB that has, in the illustrated embodiment, three heat paths horizontally toward the edges of the PCB (each heat path specifically being labeled as 20 in FIG. 1). Note however that a single horizontal heat path may be adequate in certain embodiments, and the number of horizontal heat paths is not particularly limited in number or shape. As such, there may be one, two, three, four, five or more horizontal heat paths that are defined by the embedded structure(s), which may terminate at the same or different sides of a PCB. The horizontal heat paths (for example, a coin) may terminate at an edge of the circuit board, or, in certain embodiments, the heat paths (coin (20)) may extend beyond the edge of a PCB as shown in FIG. 1 (the extension past the PCB is shown and also labeled (20). The extension of a heat path, e.g., coin, past the edge of a PCB can be beneficial is such allows for a more accessible way to attach the heat path to a system radiator or other type of heat sink, e.g., a system heat sink.

Another embodiment is shown in the cross-sectional view on FIG. 2, which is similar to the embodiment in FIG. 1, but this embodiment does not have an extension of the coin past the edge of the PCB. Instead, what is shown is that an edge of the coin is connected to a heat sink (40). In this FIG. 2, it is apparent that the PCB's body (10) is in the form of a multilayer board where components (30), such as chips, may be located on top of the board, with traces (50) connecting some or all of the components in various ways being provided at various different layers or laminates forming the board. A component may be directly mounted on the structure/coin (20), which in effect removes the heat generated by said component through conduction through the coin and away from the component toward the edge or edges of the PCB as well as toward the bottom of the PCB and through heat paths (60) provided by the coin.

In certain embodiments, the coin extends to both the top and bottom surfaces of a PCB, thereby forming one or more vertical heat paths, but without extending beyond the top or bottom surfaces of the PCB.

At one or more edges of the PCB, a heat sink (40) may be provided that has enhanced heat sinking/transfer (65) properties, which may be by radiation and/or conduction, which is typically connected to the coin directly through a thermal interface. It is to be understood that most of the heat from the electronic component will travel through the coin, and primarily toward the system heat sink (portion of system with significantly higher heat capacity relative to other elements of the thermal system) that has been provided, which may be any predetermined part of the coin, for example, one which may be connected to a surface with a high relative heat capacity (e.g. system or sub-system cold plate).

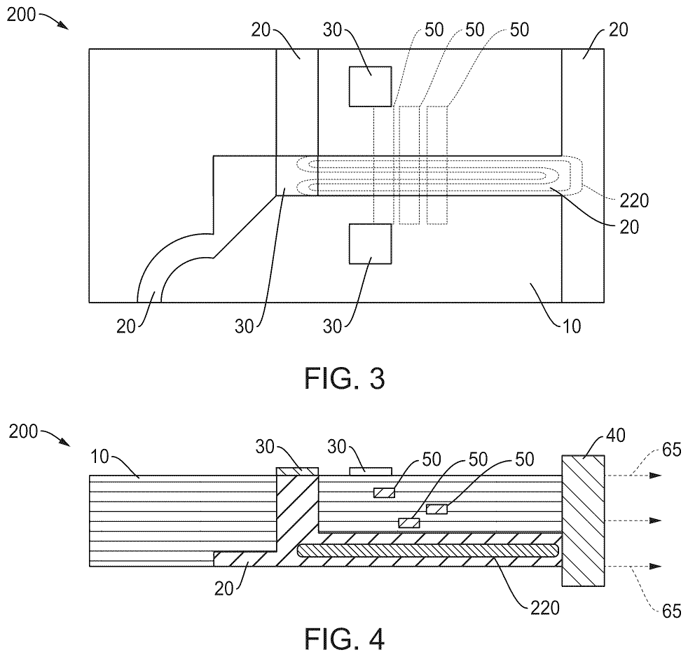

FIG. 3 as well as FIG. 4 depict the same exemplary embodiments of a PCBs as FIG. 1 and FIG. 2 respective, but therein labeled (200), and in addition illustrate that a heat path in the horizontal direction may be enhanced by the use of a heat pipe, for example, an oscillating or pulsating heat pipe (220). Such a heat pipe, e.g., an oscillating or pulsating heat pipe has a heat receiving end, also known as an evaporator section, which is located within the coin, ideally close to a heat generating component, e.g., directly under such a component, e.g., where a horizontal section of the coin overlap a vertical section. When the heat receiving end of the pipe heats up, the heated material, e.g., working fluid, in the pipe vaporizes and expands, and starts moving in vapor form toward the cooler side of the heat pipe, known as the condenser side, which may terminate close to a heat sink, where the material condenses back to liquid. The condenser side of the heat pipes can be located close to the edge of the PCB either still within the PCB or even extending beyond the edge of the PCB. The condensate from the condenser side of the pipe in liquid form then heads back toward the evaporator side of the pipe as more heated vapor is pushed therefrom to the condenser side of the pipe displacing the cooled liquid. This motion of vapor and liquid in the pipes leads to an oscillating and/or pulsating motion of liquid slugs disrupted by vapor plugs moving through the heat pipes and effectively and efficiently carrying heat from the heated side of the pipe, ideally close to a component generating heat, away from the component and toward an edge of the PCB. The working fluid can contain material that is not limited to, but is inclusive of materials such as ammonia, butane, glycerin, etc., and is inclusive also of yet to be available materials on the market.

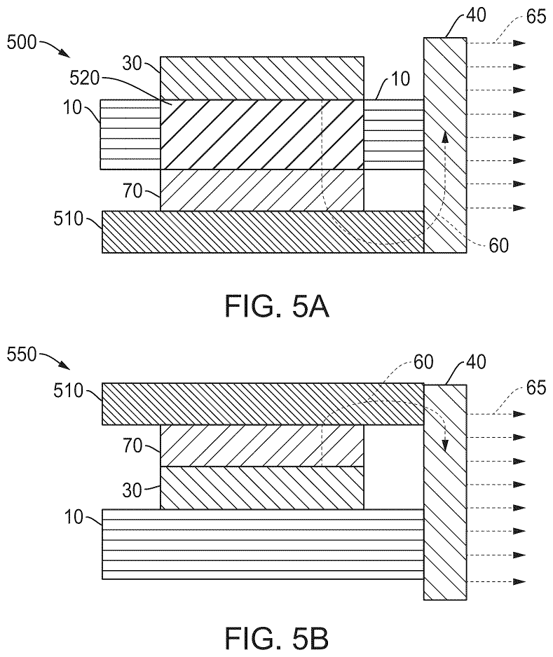

FIG. 5A illustrates a traditional setup of how heat is removed from a PCB. The option shown illustrates the use of a vertical only bottom-side heat path design (500), where a vertical-only coin (520), which is typically made of copper or of a high thermal conductivity material, is embedded into the PCB (10). In the illustrated embodiment, the heat generating electronic component (30) is located on top of the coin, and transfers heat through the coin and toward the path of lowest thermal resistance, i.e., toward the chassis (510) of the electronics package, through a thermal interface material (70). The chassis is connected to a system radiating or conductive surface (40), e.g., a system heat sink or cold plate, that has a high heat capacity relative to other elements of the thermal system, where the figure shows the heat leaving (65), e.g., to the surrounding environment. The heat may be transferred to the environment through the system heat sink or cold plate through conduction, convection, radiation, or evaporation. In this approach, a majority of the heat generated by the electronic component (30) and ultimately transferred to the system environment is transferred through the heat path (60), which is through the coin and through the thermal interface material and then the chassis and thereafter to the system radiating or conductive surface. At each interface of material change, a thermal interface is present, which would typically lead to an inefficiency in the transfer of heat. For example, thermal interfaces (not illustrated) are usually present between the electronic component and the coin, between the coin and the thermal interface material, between the thermal interface material and the chassis, as well as potentially present between the chassis and the system radiating or conducting surface.

Another option is of a traditional vertical only top-side heat path design (550) depicted in FIG. 5B. In FIG. 5B, the electronic component (30) is on the PCB (10), but there is no embedded coin, but rather from the top of the electronic component, through a thermal interface material (70) heat is conducted to the chassis (510), which is connected to a system radiating or conductive surface (40). At each interface of material change, a thermal interface is typically present, which would typically lead to an inefficiency in the transfer of heat. For example, thermal interfaces (not illustrated) are usually present between the electronic component and the thermal interface material, between the thermal interface material and the chassis, as well as between the chassis and the system radiating or conducting surface.

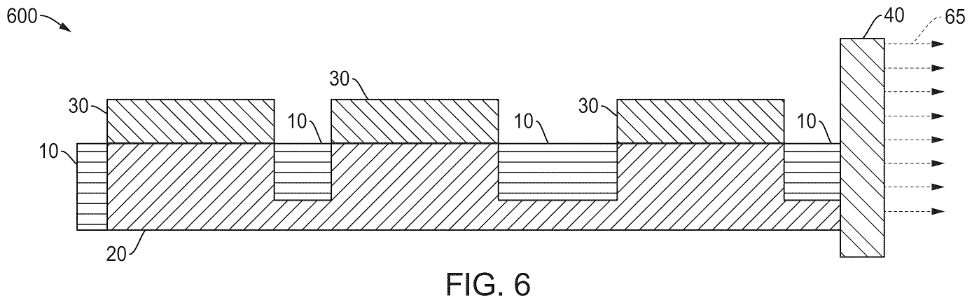

FIG. 6 depicts an embodiment (600) showing an embedded coin (20) in a PCB (10) that has multiple components (30) mounted on parts of the coin extending vertically to the top of the PCB, where the multiple component share the same coin, and, at least to a large extent, a common heat path through the shared coin. The coin in this case has three parts that extend to the top of the PCB, and on each such part an electronic component is installed. The coin then extends to the bottom of the PCB vertically and at the same time extends horizontally to an edge of the PCB where it interfaces a system radiating of conductive surface (40) that moves or transfers heat away (65) from the PCB. Thus, it is envisioned that multiple electronic component may share a single coin that is configured to transfer heat away from each of the electronic components vertically as well as horizontally.

Noted is that it is envisioned that several coins are employed in a single PCB, each transferring heat away from one or more electronic components.

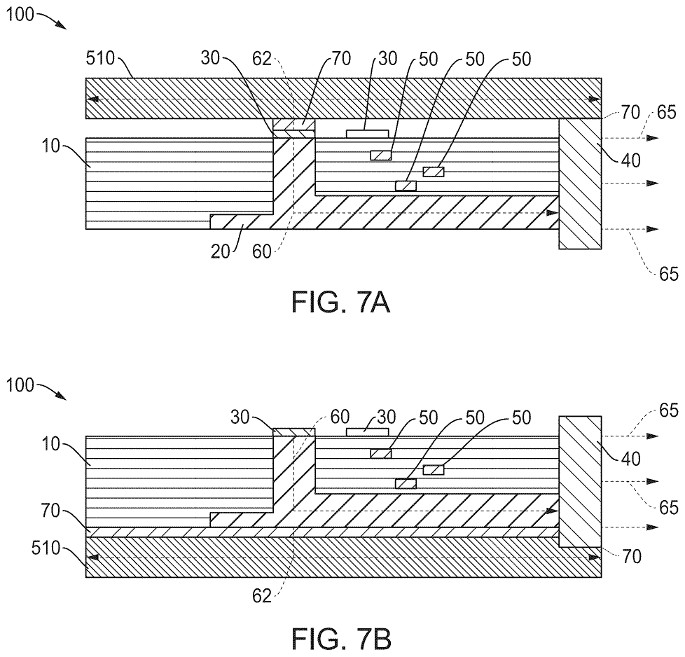

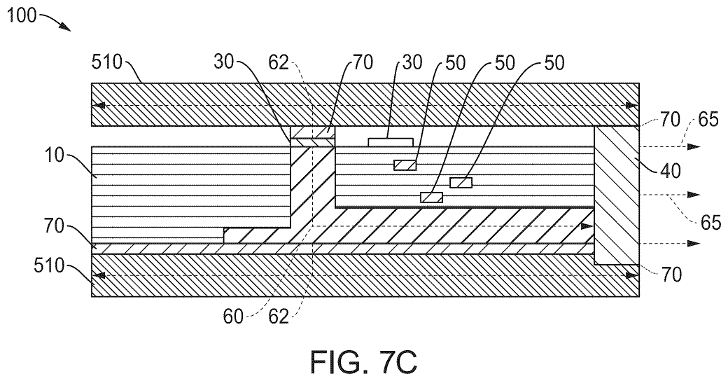

FIG. 7A shows an embodiment similar to the embodiment in FIG. 2, which includes a chassis (510) having a thermal conductivity higher than the thermal conductivity of the material forming the PCB's/PWB's body (10), which through a thermal interface material (70) connects to the electronic component (30) on the PCB/PWB. This way some of the heat generated by the electronic component is transferred through the thermal interface material (70) and through the chassis (510) through heat path (62) away from the electronic component (30). Heat path (62) thus forms a secondary heat path in addition to the primary heat path (60) to provide even further removal of heat than what may be accomplished by the primary heat path (60) alone. The chassis (510) through heat path (62) can transfer the heat to heat sink (40) through an optional further thermal interface material (70) located between the chassis and the heat sink.

FIG. 7B shows an alternate embodiment to the one shown in FIG. 7A, this embodiment also being similar to the embodiment in FIG. 2, which includes a chassis (510) having a thermal conductivity higher than the thermal conductivity of the material forming the PCB's/PWB's body (10), which through a thermal interface material (70) connects to the bottom side of the exposed area of the coin at the bottom surface of the PCB/PWB. Heat transferred from the electronic component (30) moves through the primary heat path (60) though the vertical part of the coin and thereafter, some of the heat is removed through the primary heat path (60) horizontally, but some of the heat is removed through the thermal interface (70) to the chassis (510), where the heat is further removed from the electronic component through a secondary heat path (62). This way some of the heat generated by the electronic component is transferred through part of the primary heat path (60) within the coin, and then through the thermal interface material (70) and through the chassis (510) via a secondary heat path (62) further away from the electronic component (30). Heat path (62) thus forms a secondary heat path in addition to the primary heat path (60) to provide even further removal of heat than what may be accomplished by the primary heat path (60) alone. The chassis (510) through heat path (62) can transfer the heat to heat sink (40) through an optional further thermal interface material (70) located between the chassis and the heat sink.

FIG. 7C illustrates an embodiment that utilizes both of the secondary heat paths shown in FIG. 7A and FIG. 7B, each of which operates as described above. In this embodiment, the two secondary heat paths provide an even further improved heat removal in addition to the heat removal accomplished by the primary heat path (60) within the coin.

### DETAILED DESCRIPTION OF THE INVENTION

The embodiments of the present disclosure can comprise, consist of, and consist essentially of the features and/or steps described herein, as well as any of the additional or optional ingredients, components, steps, or limitations described herein or would otherwise be appreciated by one of skill in the art. It is to be understood that all concentrations disclosed herein are by weight percent (wt. %.) based on a total weight of the composition unless otherwise indicated.

The present disclosure is directed to a PWB or PCB that uses a coin, which coin is made of a material that is inclusive of all materials that have a higher thermal conductivity than the surrounding material forming the PCB/PWB, and is inclusive of non-electrically conductive materials also that are thermally conductive, and is also inclusive of filled thermal features or sintered features, and is not limited to metals, but rather inclusive of non-metallic materials. Such higher conductivity can have, for example, 1.5 times or more, or 2 times or more, or 2.5 times of more, e.g., 2 times to 10 times more, heat conductivity than of the surrounding material forming the PCB/PWB. The coin can have any shape that provides a thermal path or channel through which heat is transferred from heat generating electronic components to a heat sink. The coin can be a press-fit coin, embedded coin, sintered coin, filled thermal feature, e.g., engineered thermal paste in a hollow part of the PCB, or any other organic or inorganic material, including composite materials, and may utilize advanced exotic thermal design techniques, e.g., inclusion of heat pipes, for example, oscillating or pulsating heat pipes in the coin, or heat pipes that are in fluid communication with a heat sink, e.g., having coolant fluid circulate between a heat sink and the coin. A coin in one embodiment creates both vertical and horizontal heat paths from an electronic component on the PCB and away from the PCB, thereby providing improved cooling to the PCB and the electronic components thereon.

The approach taken in this application preserves the ability to route electrical signals around and between the coin(s) as wiring board traces connecting electronic components can be located at different layers of a PCB and can not only be routed around a coin, but may pass above or below a coin on a layer that is not occupied by the coin. In sum, a coin may be designed to have a shape where at certain sections it is exposed at the top of the PCB and at other sections it is exposed at the bottom of the PCB, but where further sections are provided that are embedded in the PCB with space being available at a layer above and/or below the coin to allow for wire traces to be located.

The area of exposure of the coin at the bottom of the PCB may represent a significant part of the area of the bottom side of the PCB, e.g., at least 10%, at least 20%, at least 30%, at least 40%, at least 50%, at least 60%, at least 70%, at least 80%, at least 90% and even 100%. Each of these values are also understood to be disclosed to form an end point of a range of the area being exposed, e.g., 10 to 90%, 30 to 60%, 20 to 70%, 40 to 50%, etc.

The coin in an embodiment does not extend above or below the top or bottom surfaces of PCB to allow for standard solder paste application.

In an embodiment, a coin as disclosed herein provides a heat flux path with low thermal resistance directly from a component soldered to the coin to a thermal sink located at an edge of the PCB/PWB, where the thermal sink may be also soldered to the coin, or may be closely abutting such a thermal sink to allow for the efficient transfer of heat from the coin to the thermal sink primarily through conduction.

The use of PCBs/PWBs that contain features/coins in accord with the disclosure herein are capable of being used with automated production processes, including using solder stencils which are designed to print solder paste onto printed circuit boards at desired locations. Such stencils are typically formed from a metal sheet that has an electrical connection pattern cut into it that allows for the application of solder at chosen locations only, e.g., predetermined locations of electronic components on the PCB.

Provided below are some usable solder materials that are typically used in the commercial and/or military markets for PCBs/PWBs. Exemplary embodiments, which are not limited or exhaustive, include solder compositions for attaching components to printed wiring boards.

| Alloy Name | Alloy Composition | Description |
|---|---|---|
| SAC305 | SnAg3.0Cu0.5 | Tin-Silver-Copper |
| CASTIN | SnAg2.5Cu0.8Sb0.5 | Tin-Silver-Copper- |
| | | Antimony |
| SN100C | SnCuNiGe | Tin-Copper-Nickel- |
| | | Germanium |
| Tin-Lead | Sn63Pb37 | Tin-Lead |
| Tin-Lead | Sn62Pb38 | Tin-Lead |
| Tin-Lead | Sn60Pb40 | Tin-Lead |

The approach provided herein eliminates or minimizes thermal interfaces and improves thermal efficiency relative to vertical-only heat path applications of press-fit coin, embedded coin, laminated coin, or filled thermal cavity, although thermal interfaces may be present in various embodiments. By the elimination or minimization of the amount of types of materials through which the heat travels, the inefficiencies associated with heat transfer from one material to another is eliminated or minimized. As such, in one embodiment, a single material is used as the coin, to which directly without other interfacing materials being provided one or more heat generating electronic components and a heat sink are connected.

In alternate embodiments, a coin may have certain parts of it made of a different material than other parts of it. For example, the horizontal paths of a coin may be made of a different material than the vertical paths, and even within the horizontal paths, if there are several, e.g., extending to different edges of a PCB, they may be made of different materials.

A way to provide a coin that includes the use of a “filled thermal cavity”, which term describes a thermally conductive thermal material, which may be solid, sintered, or which may be another high thermal conductivity compound, which may be organic or inorganic, and which may be crystalline or amorphous, or which may be a composite material, e.g., ceramic matrix material, or a glass or ceramic material, which is applied and/or cured or otherwise formed in a single step or in multiple steps to fill a cavity that has been provided in a PCB/PWB to form a structure to serve as a heat path from an electronic component to a heat sink.

In certain embodiments, an option is to use an interconnect between traditional PWB interconnects (e.g., vias, edge plating) and the coin or thermal cavity, or heat pipes, such as oscillating or pulsating heat pipes, which then allow such interconnects to be more efficiently cooled as well, should such cooling be needed at such interconnects.

In certain embodiments, a PCB's cooling may be enhanced by the inclusion of a thermal working fluid and/or fluid channel within a coin or filled thermal cavity, which improves the thermal conductivity of the coin or filled thermal cavity, such as by the use of a heat pipe, for example, an oscillating or pulsating heat pipe, or a heat pipe that is in fluid communication with a heat sink. Due to the nature of the environment of PCBs being in electronic devices, the oscillating or pulsating heat pipes in one embodiment are closed systems that do not allow for the liquid or working fluid to escape and interact with the PCB or with electronic components thereon or with wiring board traces. Such a closed system may have a valve for charging or removing a working fluid into or out of the oscillating or pulsating heat pipe.

An approach to using heat pipes includes the use of heat pipes at least partially embedded in the coin through which a working fluid is pumped through to remove heat from the electronic devices. This approach is possible with a design that avoids the electronic components and/or PCB from interacting directly with the working fluid. Such a heat pipe may connect to a further heat pipe in a heat skink to which the PCB is connected through one or more of its surfaces or edges. In sum, this option includes a fluid connection between the heat pipe(s) in the coin and the heat sink, where the coin or filled thermal cavity has a connectorized portion of a cooling loop connected to heat pipes in a heat sink. A connectorized portion may be a fluid connection at the end of a pipe that is able to connect to another pipe. The board in such an embodiment contains and inlet and an outlet for this fluid channel, which may be at an edge of the board, which may be embedded in a horizontal part of the coin. The input and output connects to the larger system which may be outside the PWB, for example, connects to a heat sink. The pump referenced above is part of an external system and provides inlet pressure and outlet negative pressure so that the working fluid moves through the heat pipes. In this type of embodiment, the cooling loop has no restrictions regarding its path, e.g., it may extend into both the vertical and horizontal parts of the coin.

In addition to using a single coin made of the same homogeneous material, an alternate option is to use a combination of a coin, thermal cavity fill, thermal interface material, working fluid and/or working fluid channel to complete a thermal channel. The thermal channel may include several of one or more parts mentioned above, which may be of the same material or different. For example, a coin may have a section made of a different material than another section of it, each being a homogeneous material, but different from each other. The number of sections of a coin that may be made of different materials, each being homogeneous, is not limited, and may be two, three, four, five, six or even more. For example, there may be two coins made of different materials, which may be connected by a thermal cavity fill, one or both of which may employ a working fluid or working fluid channel, and which may be connected to a component and/or heat sink via a thermal interface material, e.g., a paste. In one embodiment, a vertical heat path may be made from a material that is different than a horizontal heat path, which may aid in making manufacturing easier, e.g., a horizontal portion or part of it may be made from a fill material, while a vertical portion or part of it may be made from a press fit portion. In an alternate embodiment, the material forming the coin is non-isotropic or anisotropic.

The choice for various materials in a single coin can play a role in the heat management of the PCB. A single coin material may be ideal in certain applications, but not in others. For example, a single material coin may lead to a large temperature drop between the coin and the head sink, which may have its deteriorating effects on the PCB resulting in a coefficient of thermal expansion mismatch. A way to avoid excessive heat changes between the coin and the heat sink and/or other components is to use two, three or even more coin materials which can lead to a stepwise temperature drop from material to material between the heat source, e.g., electronic component, and the heat sink instead of just having one large temperature drop where the heat sink interfaces a coin made of the same material throughout.

Reference is made to the traditional vertical only bottom-side heat path design and the traditional vertical only top-side heat path design disclosed and illustrated herein. In comparison to such embodiments, the Utilization of integrated printed wiring board coin with horizontal heat channel and edge exposure to increase heat flux provides numerous advantages, such as, for example: the use of a horizontal heat path eliminates two thermal interfaces of a traditional vertical only bottom-side heat path design; and eliminates one thermal interface of the traditional vertical only top-side heat path design.

Moreover, the use of a horizontal heat path eliminates non-ideal thermal interface materials from of traditional vertical only bottom-side and top side heat path designs.

A further advantage is that the use of a horizontal heat path eliminates the need for exotic chassis design to facilitate heat transfer (e.g., via heat pipes, oscillating heat pipes, pyrolytic graphite, etc.) found in traditional vertical only bottom-side and top-side heat path designs. In these traditional designs, the chassis has played an important role in the transfer of heat, which put design and fabrication pressure of forming elaborate or large surface area chassis to allow it to play its role efficiently in the heat management of the electronics device, which added both materials and fabrication costs, which are now minimized with the use of a horizontal also heat path design.

Furthermore, the use of a horizontal heat path as taught herein allows for a high thermal conductivity path directly from an electronic component to system heat sink (portion of system with significantly higher heat capacity relative to other elements of the thermal system), optionally with or without any further interface material between the heat path and the electronic component and/or the system radiating or conducting surface. The chassis may be completely eliminated as a heat transfer medium to which the electronic component is connected indirectly, e.g., via a thermal interface material, e.g., paste material or thermal gap pad, and/or through a coin, etc.

Furthermore, the utilization of an integrated printed wiring board coin with horizontal heat channel and edge exposure as taught herein, which also has top and bottom exposure at the top and bottom surfaces of the PCT also reduces costs. This is achieved, by, for example, the need for exotic chassis thermal designs (including those containing heat pipes, oscillating heat pipes, pulsating heat pipes, pyrolytic graphite, copper, exotic materials, etc.) and the need for manual or automated application of expensive thermal interface material with low-cost coin technology in the printed wiring or circuit board. Indeed, in many situations, thermal interface materials, e.g., paste material or thermal gap pad, may be eliminated from various thermal interfaces as the coin may smoothly and as completely as possible about electronic components and/or system radiating or conductive surfaces without the provision of such thermal interface material therebetween. The elimination or minimization of thermal interface materials additionally beneficially leads to cost savings as well as a simplification of the production of the electronic modules/systems, e.g., as steps needed to carefully place pastes and/or pieces of thermal gap pads, which in addition are often complicated by the additional step of having to remove a film or plastic liner therefrom before use. Moreover, if errors are made where, e.g., a plastic liner from a heat pad is not removed or completely removed or the paste is not applied at the proper amount, e.g., a paste dollop size is incorrect, it can lead to a defective product. In sum, the elimination or minimization of thermal interfaces simplifies production processes and makes them less costly.

Thermal interfaces, if any, may also be made of metal foil pieces such as indium foil or alloys containing indium or may be made of other materials, e.g., other metals, which is relatively soft and malleable as well as a good heat conductor, which may be used after cutting to the appropriate predetermined sizes to be placed at thermal interfaces.

Thermal interfaces may also be made of materials that are thermally and electrically conductive where the majority of the base material is not indium or indium alloy or alternatively, can be made of a variety of metallic materials where the majority of the base material is metal.

Alternatively, and optionally, the coin may be connected to the electronic components and/or system radiating or conductive surfaces by the use of a small amount of solder material, e.g., at one or more locations at the edges of connection.

In sum, the coin may be connected to the rest of the thermal system, e.g., the heat sink, by using indium or solder or other metal materials as described above.

Alternatively, a coin may be connected to the rest of the thermal system without using any additional materials, e.g., by a surface of the coin closely abutting a surface of, e.g., a heat sink.

Design options also allow for multiple electronic components to share a single low cost heat path, which heat path can efficiently remove heat toward a heat sink from multiple electronic components provided thereon, e.g., at various locations of the coin that extend to the top surface of the PCB.

In certain embodiments, where significant amount of heat is required to be removed in an efficient manner, one can use a working fluid or working fluid path to be included in coin to achieve thermal conductivity above that of copper. In other words, any material chosen for the coin material, including pyrolytic graphite, copper, or exotic materials, etc., may have its heat transfer ability enhanced or improved by the further use of a working fluid, for example, by the use of a heat pipe, an oscillating or pulsating heat pipe within the coin.

Further aspects include utilization of an integrated printed wiring board coin with horizontal heat channel and edge exposure to reduced complexity, time-to-market, and cost-to-market, each of which represent significant additional advantages. The simple approach to providing a coin that has exposure at both the top and bottom of a PCB as well as it provides a heat path to the edge of the PCB allows for simple fabrication procedures to efficiently and cost effectively produce PCBs that have advanced heat removal abilities without having to spend efforts and costs on other aspects, like complicated chassis design.

For Example, the design and fabrication of chassis that includes features like oscillating heat pipes or other types of heat removal pipes is expensive and can dominate product development schedule. Eliminating those elements of a system's thermal design reduces the systems complexity and drives lower cost and shorter schedule to provide a product all the way to market.

Moreover, application of thermal interface material in a high-volume production environment typically involves calibration and integration of automatic deposition/placement machines in a production line. The elimination of thermal interface material in a system's thermal design, or at least the reduction thereof to some extent, reduces the system's complexity and drives lower cost and shorter schedule.

Other benefits of the utilization of an integrated printed wiring board coin with horizontal heat channel and edge exposure allows for increased mission capabilities, for example, in electronics involved in military applications and even civilian applications, reduced weight of products as less overall material is needed to efficiently remove heat from electronic components/chips from a PCT, and even increase product life by the elimination of materials or components that may otherwise be susceptible to shorter lifespans, e.g., due to corrosion, susceptibility to impact damage, etc.

The herein disclosed PCBs with the structures/coins as provided herein, one can achieve lower junction temperatures generally resulting in increased thermal efficiency for the system and longer component life.

Advantageously, the herein disclosed PCBs with the structures/coins as provided herein, create a thermal flux management system that allows for greater thermal and functional density (e.g., more components may be packed more densely on a PCB) as the heat removal efficiency is significantly increased by the use of a coin having both top and bottom exposure at the top and bottom sides of a PCB as well as horizontal exposure to one or more edges of the PCB.

With such significant increased heat removal efficiency, one can eliminate or reduce the need for heavy and complex chassis designs, be able to avoid or at least reduce the use of expensive or heavy materials such as copper, indium, gold, silver, or other non-limiting materials that have yet to be known, thereby providing savings of both costs and effort in providing a compact electronics package. This, thus therefore, lead to lower cost/complexity for component packaging.

Moreover noted is that the coins provided in the PCBs as disclosed herein allow for the use of PCB/PWB pick-and-place process that uses industry standard solder stencils by preserving coplanarity of PWB surface. This is a reason why the top and bottom exposed parts of a coin should not extend past the top or bottom surfaces of the PCB.

And as mentioned above, with a proper design adapted in each case for a particular board, electrical routing layers may be preserved and can coexist with extensive coin sizes having various shapes that allow for the electrical routing layers to pass within layers above and/or below parts of the coin as well as, of course, around a coin within a PCB/PWB. A possible option is also to have a routing layer that has part of the coin below and above said routing layer. These design options allow for preserving sufficient areas within the PCB/PWB for high electrical functionality while providing efficient heat removal from the PCB/PWB.

In a further embodiment, use may be made of existing PCB/PWB coin technologies to add vertical heat paths to system radiating or conducting surfaces. In this regard, exposed surfaces of the coin, for example, on the bottom of a PCB where no electronic component is present (although in some embodiments electronic component/chips may be present on both the top and bottom surfaces of a PCB), or even at the top at areas where no electronic component is present, the exposed surface of the coin may contain ridges or have a roughening to provide a higher surface area compared to an otherwise identical coin that has a smooth surface. Such roughening of surfaces of the coin may lead to higher heat removal by radiation or convection, which may be enhanced by the provision of moving air across said surface, e.g., by an optional cooling fan. While the primary cooling method may still be the conduction of heat from one material to another, e.g., from the coin to a system radiating or conducting surface, where the interface among those material should be as smooth and abutting to each other as possible, the further removal of heat by radiation or convection further enhances the overall cooling accomplished for the PCB and the electronic components thereon. Noted is that even if a surface roughening or ridges are provided, the top peaks of the roughening or ridges should not extend above the surface of the PCB.

In certain embodiments, all exposed surfaces of a coin, including at the top or bottom of a PCB and the edges thereof, may be smooth. Such options allow for further locations for electronics components to be attached, e.g., soldered thereto.

Further noted is that the use of coins, but not limited to thermal filled structures, in PCBs as provided herein allows for the applicability thereof to open architecture form factors, such as, for example, VPX and VNX.

A way to fabricate coins for PCB usage, includes the use of additive manufacturing processes, including 3D printing. This is particularly useful in situations where a PCB has a complex shape and/or contains one or more heat pipes, e.g., oscillating or pulsating heat pipes.

Further options include a variety of standard approaches, including laminating, plating, sintering, etching or machining coins that may be inserted into a PCB.

Further options include the production of PCBs that contain a cavity to be filled by a thermally conductive material, i.e., a ‘filled thermal cavity’ being provided within a printed wiring board. The fabrication can take into account that in each situation the desired heat conductivity of the path provided by the coin can be adapted to meet the desired heat removal performance, e.g., by not only selecting the size and shape of the coin, but also by selecting appropriate material for the coin.

To provide a filled thermal cavity, a cavity having been provided in the PCT is filled with thermally conductive material where the thermal conductivity is chosen to be greater than the thermal conductivity of the average surrounding printed wiring board laminate material. Typically, the filled thermal cavity thermal conductivity is at least twice that of the average surrounding printed wiring board laminate material, but such can be chosen differently as well.

The thermally conductive material may be a flowable thermally-conductive paste, which may be used to fill cavities in PCBs/PWBs to create thermal channels in the form of an in place formed coin. Such pastes may be cured or sintered. Sintering options are particularly useful for vertical channels.

Typically, the coefficient of thermal expansion is higher for the coin, e.g., copper, aluminum, steel, e.g., stainless steel, or other metal alloy or composite material, than for the other materials forming the layers of a printed circuit or wiring board, and as such, especially with coins having various shapes and sizes, consideration may be needed of stresses caused by the coin on the PCB. Such stresses may be minimized by providing at certain locations a material that is compressible or compliant, which can account for the displacement of the coin's expansion without causing excessive stress on the entire PCB, which could cause stress cracks, warping and/or other deformations, which can happen on the PCB layer forming materials, including on ceramic materials, as well as on solder interfaces or even across wiring traces, which can lead to failure of the wiring board. An alternate option is to use interface material that likewise can reduce stresses caused by the expansion of coin material.

While the present disclosure has been particularly described, in conjunction with specific preferred embodiments, it is evident that many alternatives, modifications and variations will be apparent to those skilled in the art in light of the foregoing description. It is therefore contemplated that the appended claims will embrace any such alternatives, modifications and variations as falling within the true scope and spirit of the present disclosure.

What is claimed is:

1. A printed circuit board or printed wiring board (PCB/PWB), comprising
a multilayer structure forming the PCB/PWB, which has a top surface, a bottom surface and several sides,
embedded within the PCB/PWB a coin made of a material having higher heat conducting properties compared to the material of the PCB/PWB,
wherein the coin has at least one exposed area at the top and/or bottom surface of the PCB/PWB onto which exposed area an electronic component can be attached,
wherein the coin may or may not have an exposed area at the opposite surface of the PCB/PWB,
and
wherein at least one part of the coin extends to a side of the PCB/PWB where said at least one part is exposed on a side of the PCB/PWB, or where at least one part of the coin extends past a side of the PCB/PWB where said at least one part extending is exposed.

2. A printed circuit board or printed wiring board according to claim 1, further comprising an electronic component that is attached to the coin at the at least one exposed area at the top and/or bottom surface of the PCB/PWB.

3. A printed circuit board or printed wiring board according to claim 1, further comprising a system heat sink that is connected to the coin extending to at least one side of the PCB/PWB or extending past at least one side of the PCB/PWB.

4. A printed circuit board or printed wiring board according to claim 1, further comprising a system radiating or conducting surface that is connected to the coin extending to at least one side of the PCB/PWB or extending past at least one side of the PCB/PWB, wherein a thermal interface material is present between the coin and the system radiating or conducting surface or a system heat sink.

5. A printed circuit board or printed wiring board according to claim 1, wherein a part of the coin extends past at least one side of the PCB/PWB.

6. A printed circuit board or printed wiring board according to claim 1, wherein the at least one exposed area at one or more surface(s) of the PCB/PWB contains ridges or has a roughening to provide a higher surface area compared to an otherwise identical coin that has a smooth surface.

7. A printed circuit board or printed wiring board according to claim 1, further comprising an electronic component that is attached to the coin at the at least one exposed area at the top and/or bottom surface of the PCB/PWB to which electronic component a chassis is connected through a thermal interface material, which chassis is connected to a system radiating or conducting surface through an optional thermal interface material.

8. A printed circuit board or printed wiring board according to claim 1, further comprising an electronic component that is attached to the coin at the at least one exposed area at the top and/or bottom surface of the PCB/PWB, wherein the surface of the area of the exposed part of the coin at the opposite surface of the PCB/PWB is connected through a thermal interface material to a chassis, which chassis is connected to a system radiating or conducting surface through an optional thermal interface material.

9. A printed circuit board or printed wiring board according to claim 1, wherein two, three or four parts of the coin extend to two, three or four sides of the PCB/PWB where each are independently either exposed on a side of the PCB/PWB or extend past a side of the PCB/PWB.

10. A printed circuit board or printed wiring board according to claim 1, wherein two or more exposed areas of the coin are present at the top and/or bottom surface of the PCB/PWB onto each of which exposed areas an electronic component can be attached.

11. A printed circuit board or printed wiring board according to claim 1, wherein two or more exposed areas of the coin are present at the top and/or bottom surface of the PCB/PWB onto each of which exposed areas an electronic component has been attached directly by a solder material.

12. A printed circuit board or printed wiring board according to claim 1, further comprising wiring traces in the PCB/PWB below and/or above and/or around parts of the coin.

13. A printed circuit board or printed wiring board according to claim 1, wherein the area of the exposed part of the coin at the top and/or bottom surface of the PCB/PWB represent at least 20% of the area of the bottom surface of the PCB/PWB.

14. A printed circuit board or printed wiring board according to claim 1, further comprising an electronic component that is attached to the coin at the at least one exposed area at the top and/or bottom surface of the PCB/PWB and a system radiating or conducting surface that is connected to the coin extending to at least one side of the PCB/PWB or extending past at least one side of the PCB/PWB, wherein the electronic component and the system radiating or conducting surface are soldered to the coin.

15. A printed circuit board or printed wiring board according to claim 1, wherein different sections of the coin are each made of different homogeneous materials.

16. A printed circuit board or printed wiring board (PCB/PWB), comprising a multilayer structure forming the PCB/PWB, which has a top surface, a bottom surface and several sides,
embedded within the PCB/PWB a coin made of a material having higher heat conducting properties compared to the material of the PCB/PWB,
wherein the coin has at least one exposed area at the top and/or bottom surface of the PCB/PWB onto which exposed area an electronic component can be attached,
wherein the coin has at least one exposed area at the opposite surface of the PCB/PWB,
wherein at least one part of the coin extends to at least one side of the PCB/PWB where said at least one part is exposed on at least one side of the PCB/PWB, or where at least one part of the coin extends past at least one side of the PCB/PWB where said at least one part extending is exposed;
and
comprising a heat pipe in at least one part of the coin extending to a side of the PCB/PWB or past a side of the PCB/PWB,
or
comprising a heat pipe in at least one part of the coin that can be in fluid communication with a heat sink.

17. A printed circuit board or printed wiring board according to claim 16, wherein the heat pipe is an oscillating or pulsating heat pipe that is a closed loop heat pipe.

18. A printed circuit board or printed wiring board according to claim 16, wherein the coin containing a heat pipe has been manufactured by an additive manufacturing technique.

19. A printed circuit board or printed wiring board according to claim 16, which contains a heat pipe in at least one part of the coin and extends past a side of the PCB/PWB such that part of the heat pipe is embedded in the coin and part of the heat pipe is external to the coin and also external to the PCB/PWB, and wherein a working fluid is present in the heat pipe and forms a working fluid loop that is partially inside the coin and partially exterior to the coin and PCB/PWB.

20. A process for preparing a printed circuit board or printed wiring board (PCB/PWB), said PCB/PWB comprising
a multilayer structure forming the PCB/PWB, which has a top surface, a bottom surface and several sides,
embedded within the PCB/PWB a coin made up of a material having higher heat conducting properties compared to the material of the PCB or PWB,
wherein the coin has at least one exposed area at the top and/or bottom surface of the PCB/PWB onto which exposed area an electronic component can be attached,
wherein the coin has at least one exposed area at the opposite surface of the PCB/PWB, and
wherein at least one part of the coin extends to at least one side of the PCB/PWB where said at least one part is exposed on a side of the PCB/PWB, or where at least one part of the coin extends past at least one side of the PCB/PWB where said at least one part extending is exposed;
and
said process comprising
embedding the coin in the PCB/PWB by providing laminates above, below and/or around the coin, by a plating process, by installed post PCB/PWB fabrication by press fitting the coin into a cavity formed in the PCB/PWB by mechanical force or by the aid of laser drilling, or a sintering technique to form the coin in place.
